(19) United States
(12) Patent Application Publication
(10) Pub. No.: US 2017/0164680 A1
(43) Pub. Date: Jun. 15, 2017

(54) SHOE WITH CHARGING FUNCTION

(71) Applicants: LE HOLDINGS (BEIJING) CO., LTD., Beijing (CN); LEMOBILE INFORMATION TECHNOLOGY (BEIJING) CO., LTD., Beijing (CN)

(72) Inventor: Xinghua Ge, Beijing (CN)

(21) Appl. No.: 15/245,812

(22) Filed: Aug. 24, 2016

Related U.S. Application Data
(63) Continuation of application No. PCT/CN2016/088851, filed on Jul. 6, 2016.

(30) Foreign Application Priority Data
Dec. 14, 2015 (CN) 201521036468.2

(51) Int. Cl. A43B 3/00; H02J 7/00; H01L 41/113; A43B 17/00

(52) U.S. Cl. CPC A43B 3/0015; A43B 17/006; H02J 7/0045; H02J 7/0027; H01L 41/113

(57) ABSTRACT

The present disclosure discloses a shoe with charging function, including a shoe body, an electricity generating apparatus, a battery, and an output interface, wherein: the electricity generating apparatus is configured to convert work done by a pressure applied to the apparatus into electrical energy, is mounted at the heel of the shoe body and electrically connected to the battery; and the battery is mounted at the counter of the shoe body and configured to connect the output interface for connecting a charging wire. In a process of running or walking, the shoe with charging function converts work done by a pressure applied to the apparatus into electrical energy stored by a battery, thereby eliminating certain defects of conventional charging manners, and meantime charging a mobile terminal. In periods of not being charged, surplus electrical energy is stored in the battery, environment-friendly, safe, and convenient.

### CROSS REFERENCE TO RELATED APPLICATIONS

This application is a continuation of International Application No. PCT/CN2016/088851, filed on Jul. 6, 2016, which is based upon and claims priority to Chinese Patent Application No. 201521036468.2, filed on Dec. 14, 2015, the entire contents of which are incorporated herein by reference.

### TECHNICAL FIELD

The present invention relates to the technical field of chargeable devices, and more particularly, to a shoe with charging function.

### BACKGROUND

At present, with the constant development of mobile terminals such as mobile phones, the mobile terminals become essential objects in people's daily lives. However, during the frequent use of a mobile phone every day, an emergency in which the mobile phone runs out of energy usually occurs. In such cases, no operation can be further performed, and such a helpless and embarrassing condition cannot be solved without a charging facility such as a power supply. In such cases, the nuisance of insufficient mobile phone energy in emergencies may be greatly solved if a person can generate electricity by himself/herself without the help of an external force.

An existing charging technology includes a portable mobile power pack, a solar-energy power pack, fast charging, and conventional plug charging. However, (1) a conventional charging device and fast charging cannot accommodate the demands for portability when a person goes outside; (2) the portable mobile power pack itself needs charging before it can be used, and as the capacity power of mobile power packs become higher, the mobile power packs are becoming heavier, which is inconvenient to carry together with a mobile phone; and (3) the solar-energy mobile power pack is very inconvenient for connecting to a mobile phone, and a charging speed is very low; the solar-energy mobile power pack can be used only in condition with sunshine, and cannot be used to solve emergencies.

### SUMMARY

In view of the above, an objective of the present invention is to provide a shoe with charging function to solve the technical problem of insufficient energy of a mobile terminal in emergency cases.

Based on the foregoing objective, a shoe with charging function provided by the present invention include a shoe body, an electricity generating apparatus, a battery, and an output interface, wherein:

the electricity generating apparatus is configured to convert work done by a pressure applied to the electricity generating apparatus into electrical energy, is mounted at the heel of the shoe body, and is electrically connected to the battery; and

the battery is mounted at the counter of the shoe body, and is configured to connect the output interface for connecting a charging wire.

According to the above, it can be seen that in a process of running or walking, shoes with charging function provided by the present invention converts work done by a pressure applied to an electricity generating apparatus into electrical energy, which is stored by a battery, thereby eliminating certain defects (without carrying a mobile power pack and considering the inconvenience of solar energy) of conventional charging manners, and charging a mobile terminal in the process of movement. In periods in which a mobile terminal is not being charged, surplus electrical energy is stored in the battery, which has low carbon emission and environment-friendly, safe, and convenient.

### BRIEF DESCRIPTION OF THE DRAWINGS

One or more embodiments are illustrated by way of example, and not by limitation, in the figures of the accompanying drawings, wherein elements having the same reference numeral designations represent like elements throughout. The drawings are not to scale, unless otherwise disclosed.

FIG. 1 is a schematic structural diagram illustrating a shoe with charging function according to an embodiment of the present invention;

FIG. 2 is an internal structural diagram illustrating a shoe according to an embodiment of the present invention;

FIG. 3 is a schematic structural diagram illustrating a shoe with charging function according to another embodiment of the present invention;

FIG. 4 is a schematic diagram illustrating a connection between an electricity generating apparatus and a battery according to an embodiment of the present invention;

FIG. 5 is a schematic diagram illustrating a connection between an electricity generating apparatus and a battery according to another embodiment of the present invention; and

FIG. 6 is a schematic structural diagram illustrating a shoe with charging function that has been fixed to a user according to an embodiment of the present invention.

### DETAILED DESCRIPTION

To make the objectives, technical solutions, and advantages of the present invention clearer, the following describes the present invention in more detail with reference to specific embodiments and accompanying drawings.

Nowadays, young people pay much attention to everyday physical exercise, and they usually take a mobile phone for counting steps and timing during running. If the mobile phone runs out of energy in such cases, monitored data may be lost. In such cases, work done by a pressure from running may be converted into electrical energy, which may be stored to power a mobile terminal such as a mobile phone, so as to solve an everyday problem that a mobile phone runs out of energy, and charge the mobile phone with the motion under emergencies, which reflects the concept of low carbon emission and environment protection. Therefore, a shoe with charging function provided by the present invention includes a shoe body, an electricity generating apparatus, a battery, and an output interface; the electricity generating apparatus is mounted at a heel of the shoe body, is configured to convert work done by a pressure applied to the electricity generating apparatus into electrical energy, and is connected to the battery; the battery is mounted at a counter of the shoe body, and is configured to connect the output interface for connecting a charging wire.

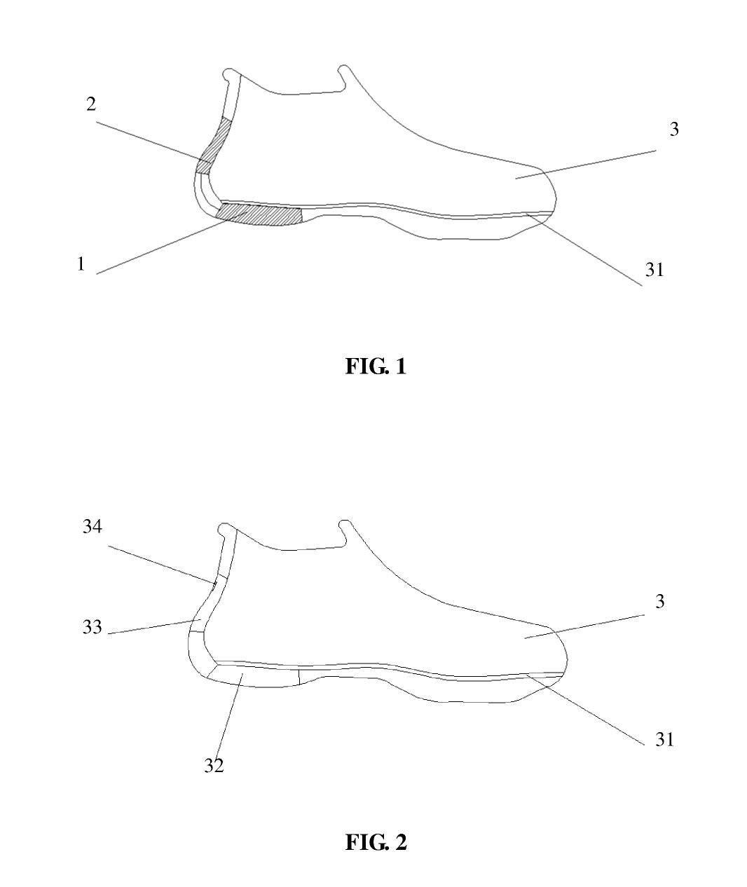

Referring to FIG. 1, FIG. 1 is a schematic structural diagram of a shoe with charging function according to an embodiment of the present invention. As an embodiment of the present invention, the shoe with charging function includes a shoe body 3, an electricity generating apparatus 1, a battery 2 electrically connected to the electricity generating apparatus 1, and an output interface (not shown in the figure). The electricity generating apparatus 1 is mounted at a heel of the shoe body 3, is configured to convert work done by a pressure applied to the electricity generating apparatus 1 into electrical energy, and transfer the electrical energy to the battery 2; the battery 2 is mounted at a counter of the shoe body 3, and is configured to store the electrical energy; the battery 2 is further configured to connect the output interface for connecting a charging wire to be used to charge a mobile terminal such as a mobile phone. Optionally, the output interface is a USB port.

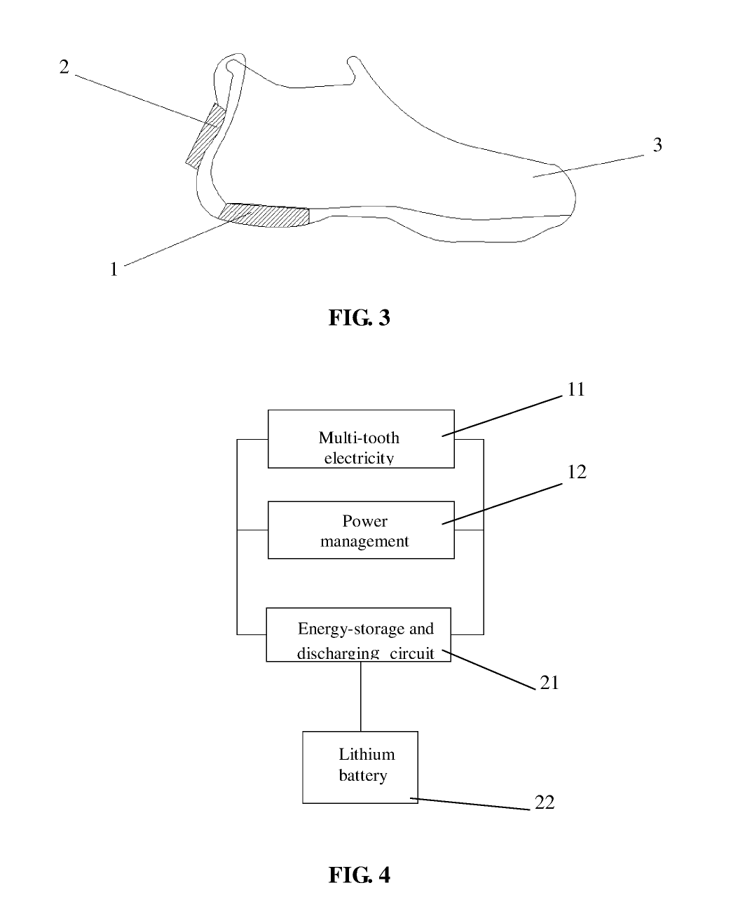

It can be seen that, the shoe with charging function provided by the present invention has the electricity generating apparatus 1 and the battery 2 mounted at the shoe body, as shown in FIG. 1 and FIG. 3; the electricity generating apparatus 1 is mounted at the heel of the shoe body 3; in a process in which a person runs or walks, work done by a pressure applied by the person to the electricity generating apparatus 1 is converted into electrical energy, and then the electrical energy is output to the battery 2 by using the electricity generating apparatus 1, and the battery 2 stores the electrical energy whose voltage has been regulated to charge a mobile terminal such as a mobile phone, an iPad, an MP3, or an MP4. As a preferred embodiment, the electricity generating apparatus 1 is a micro electricity generating apparatus to avoid affecting the motion of a person; moreover, the electricity generating apparatus 1 is mounted at the heel of the shoe body 3 (that is, a location where the heel of the user's foot applies force), so as to effectively do work on the electricity generating apparatus, thereby improving an electrical energy conversion rate. In another embodiment of the present invention, the pressure is a force along the direction of the gravity; that is, the electricity generating apparatus 1 converts work done by a pressure applied to the electricity generating apparatus 1 along the direction of the gravity into electrical energy, so that a person may directly apply a force to the electricity generating apparatus 1 at the heel, thereby improving the amount of electrical energy of the power supply device.

As another embodiment of the present invention, as shown in FIGS. 1 and 2, the heel of the shoe body 3 is provided with a bottom groove 32, the electricity generating apparatus 1 is embedded in the bottom groove 32 with an upper end in contact with a lower surface 31 of the shoe body 3, so as to make the user more comfortable when stepping on the electricity generating apparatus 1, which produces no difference from a common shoe. Further, the counter of the shoe body 3 is provided with a side groove 33 and a connection via hole 34, the battery 2 is embedded in the side groove 33, and the connection via hole 34 is aligned directly toward the output interface of the battery 2, so that the charging wire may pass through the connection via hole to be plugged into the output interface of the battery 2. Therefore, in the present invention, the electricity generating apparatus 1 and the battery 2 are hidden in the shoe body 3 in a smart way, which looks no differently from a common shoe, and does not affect physical exercise and walking.

In another embodiment of the present invention, openings of the bottom groove 32 and the side groove 33 both face toward the inside of the shoe body 3; therefore, the user may take the electricity generating apparatus 1 and the battery 2 off the shoe body 3 according to requirements, and use or wash the shoe body 3 as a common shoe. More preferably, the bottom groove 32 and the side groove 33 are respectively higher than the electricity generating apparatus 1 and the battery 2; after the electricity generating apparatus 1 and the battery 2 are respectively placed into the bottom groove 32 and the side groove 33, a buffer layer may be further placed at the openings of the bottom groove 32 and the side groove 33, so as to make the shoe with charging function more comfortable to use.

Optionally, as shown in FIG. 3, the connection via hole 34 faces toward the outside of the shoe body 3, and the connection via hole 34 is covered with a cap, so as to preventing dirt or water from entering the output interface of the battery 2. Optionally, the cap may be separately provided, that is, can be completely removed from the connection via hole 34; or the cap may be connected near the connection via hole 34 to avoid loss.

As another embodiment of the present invention, as shown in FIG. 3, the heel of the shoe body 3 is provided with an opening facing toward the inside of the shoe body 3, the electricity generating apparatus 1 is embedded in the bottom groove 32 with an upper end in contact with a lower surface of an insole 31 of the shoe body 3, and the insole 31 is placed over the electricity generating apparatus 1 (which is same as the previous embodiment). The battery 2 is mounted at an outer surface of a counter by using an adhesion fastener or a fixing clip, and the output interface of the battery 2 faces toward the top of the shoe body 3 or the rear of the shoe body 3. The battery 2 is fixed to the shoe body 3 by using a fixing clip, which, on one hand, may improve the bonding between the battery 2 and the shoe body 3 to avoid the battery 2 from falling off during running or walking, and on the other hand, may make it convenient to take the battery 2 off the shoe body 3. In this embodiment, the battery 2 is mounted outside the shoe body 3; certainly, the mounting location of the battery 2 may be flexibly changed by using an adhesion fastener or a fixing clip; the best place is at the rear of the counter, so as to avoid affecting the physical exercise or walking of the user. It should be noted that the electricity generating apparatus 1 and the battery 2 in this embodiment may also be taken off the shoe body 3, and be used or washed as a common shoe.

In another embodiment of the present invention, both the electricity generating apparatus 1 and the battery 2 are wrapped by a thin water-proof film, so as to protect the electricity generating apparatus 1 and the battery 2 from being damped with water, thereby improving security. More preferably, the insole 31 of the shoe body 3 includes an insulation layer and an exposure layer, the insulation layer is provided between the electricity generating apparatus 1 and the exposure layer, and the insulation layer and the exposure layer are of a same size. The insulation layer can avoid risks of electricity leakage, and the exposure layer ensures that the foot is comfortable with the insole 31.

In another embodiment of the present invention, as shown in FIG. 4, the electricity generating apparatus 1 includes a multi-tooth electricity generating film 11 and a power management circuit 12. The power management circuit 12 is connected to the multi-tooth electricity generating film 11 through a wire, and is configured to transfer electrical energy output by the multi-tooth electricity generating film 11 to the battery 2. Therefore, when a force is applied to the multi-tooth electricity generating film 11, a positive pole surface and a negative pole surface of the multi-tooth electricity generating film 11 deform, so as to produce friction and contact between positive and negative pole surfaces to generate electrical energy; electrical energy output (in parallel) by the multi-tooth electricity generating film 11 is transferred by the wire to the power management circuit 12, and the power management circuit 12 perform voltage regulating processing on collected electrical energy, and electrical energy whose voltage has been regulated is transferred to the battery 2 through the wire.

Further, in another embodiment, the battery 2 includes an energy-storage and discharging circuit 21 and a lithium battery 22, the energy-storage and discharging circuit 21 is separately connected to the power management circuit 12 and the lithium battery 22, and the energy-storage and discharging circuit 21 stores electrical energy into the battery 22, and can also supply stored electrical energy to a mobile terminal. Preferably, the USB port on the battery 2 connects the battery 2 to the mobile terminal for charging operation.

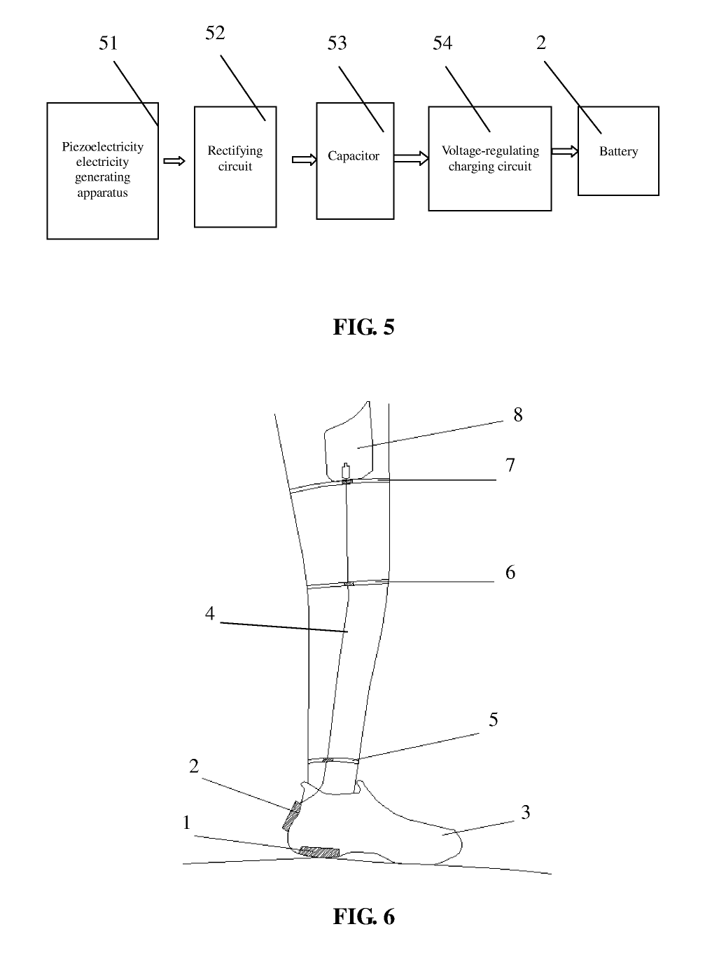

In another embodiment of the present invention, as shown in FIG. 5, the electricity generating apparatus 1 includes a piezoelectricity electricity generating apparatus 51, a rectifying circuit 52, a capacitor 53, and a voltage-regulating charging circuit 54 that are connected one by one, and the voltage-regulating charging circuit 54 is connected to the battery 2.

A piezoelectricity vibrator in the piezoelectricity electricity generating apparatus 51 has alternating characteristics in terms of voltage and current under an alternating external force or a regular impact; however, a voltage-regulated current is required to charge the battery 2. Therefore, the rectifying circuit 52 is required to perform current rectification. The capacitor 53 is configured to store electrical energy that is generated by the piezoelectricity electricity generating apparatus 51, so as to improve voltage; in order to improve output voltage as much as possible, a triple-voltage rectifying circuit may be designed, which may be implemented by preferably selecting a super capacitor. Finally, electrical energy is output to the battery 2 after the voltage-regulating charging circuit 54 performs voltage regulation and eliminates instantaneous voltage leaps. Preferably, the piezoelectricity electricity generating apparatus is selected from a piezoelectricity ceramic electricity generating apparatus, which can convert very tiny mechanical vibration and movement and a pressure applied by the heel to a piezoelectricity sheet of the heel into electrical energy through positive piezoelectricity effects, and may reduce a weight of the shoe with charging function, where multiple piezoelectricity sheets may be connected in series or parallel to obtain required voltage and current.

In this embodiment, the battery 2 is a micro battery, and may include an energy-storage and discharging circuit 21 and a lithium battery 22, the energy-storage and discharging circuit 21 is separately connected to the voltage-regulating charging circuit and the lithium battery 22, and is configured to store electrical energy into the battery 22, and supply stored electrical energy to a mobile terminal.

It should be noted that in the above embodiment, the piezoelectricity electricity generating apparatus may also be replaced with a multi-tooth electricity generating film or an electricity-generating solenoid, so that electrical energy generated by a motion of cutting a magnetic line by the electricity-generating solenoid is fully used as electrical energy.

In another embodiment of the present invention, the shoe with charging function further include a charging wire configured to connect the battery 2 and a mobile terminal, which has a suitable length and is capable of extending from a foot of a user to a root of a thigh. Specifically, as shown in FIG. 6, a charging wire 4 is connected to the battery 2; one end of the charging wire 4 is connected to the battery 2, and another end is connected to a mobile terminal; when the battery 2 and the mobile terminal are connected by using the charging wire 4, the battery 2 may charge the mobile terminal. In such cases, when a person runs or walks, the mobile terminal such as a mobile phone may be connected to the charging wire 4, so that the battery 2 charges the mobile terminal; that is, the mobile terminal may be charged in the process of physical exercise. In periods in which a mobile terminal is not being charged, surplus electrical energy is stored in the battery 2, which has low carbon emission and is environment-friendly.

It should be noted that because a person generally has an object storing space 8 such as a pocket or a waist package for storing a mobile terminal, the mobile terminal may be placed in the object storing space 8; as shown in FIG. 6, the charging wire 4 extends from the rear of the shoe body 3 to the object storing space 8 and charges the mobile terminal in the object storing space 8; in this way, when a person runs or walks, the mobile terminal such as a mobile phone may be placed in the object storing space 8 and be connected through the charging wire 4 to the battery 2 for charging.

In another embodiment of the present invention, the shoe with charging function further includes several fixing straps for fixing the charging wire 4 to a leg of the user. Specifically, as shown in FIG. 6, the shoe with charging function further includes a first fixing strap 5, a second fixing strap 6, and a third fixing strap 7, the first fixing strap 5 is configured to fixing the charging wire to an ankle of the user, the second fixing strap 6 is configured to fix the charging wire above a knee of the user, and the third fixing strap 7 is configured to fix the charging wire to the thigh of the user. Through the joint bonding by using three fixing straps, the charging wire 4 having a certain length may be firmly fixed to the leg of the user, which prevents the charging wire 4 from shake or wrapping.

As mentioned before, a person generally has an object storing space 8 such as a pocket or a waist package for storing a mobile terminal; therefore, a fixing location of the third fixing strap 7 may be close to an opening of the object storing space, so that the charging wire 4 is firmly connected to the mobile terminal, thereby preventing them from detaching.

Optionally, a manner in which the fixing straps 5, 6, and 7 are bonded with the charging wire 4 is not limited, which may be fixedly bonded to the charging wire or be removably bonded to the charging wire. Specifically, if the fixing straps 5, 6, and 7 are fixedly bonded to the charging wire 4, connection locations of the fixing straps 5, 6, and 7 and the charging wire 4 cannot be changed, but the bonding there between is more firm, and no relatively movement may occur. If the fixing straps 5, 6, and 7 are removably connected to the charging wire 4, for example, the fixing straps 5, 6, and 7 are adhesion straps or buttoned straps, two ends of the fixing straps 5, 6, and 7 can be removably connected by using a hook surface and a burr surface, and a removable connection may also be implemented by using buttons and button holes, thereby changing mounting locations of the fixing straps according to the requirements of the user.

As described above, in a process of running or walking, the shoe with charging function provided by the present invention converts work done by a pressure applied to an electricity generating apparatus into electrical energy, which is stored by a battery, thereby eliminating certain defects (without carrying a mobile power pack and considering the inconvenience of solar energy) of conventional charging manners, and charging a mobile terminal in the process of movement. In periods in which a mobile terminal is not being charged, surplus electrical energy is stored in the battery, which has low carbon emission and environment-friendly, safe, and convenient.

A person of ordinary skills in the art should understand that: the discussion of any embodiment above is merely exemplary, and is not intended to imply that the scope (including the claims) of the disclosure is limited to such examples; With the idea of the present invention, technical features in the embodiment above or in different embodiments may also be combined, and steps may be implemented in any order, and there are many other changes in different aspects of the present invention, which are not provided in detail for the sake of brevity. Therefore, any omission, modification, equivalent replacement, or improvement made without departing from the spirit and principle of the present invention should fall within the protection scope of the present invention.

What is claimed is:

1. A shoe with charging function, comprising a shoe body, an electricity generating apparatus, a battery, and an output interface, wherein:
the electricity generating apparatus is configured to convert work done by a pressure applied to the electricity generating apparatus into electrical energy, is mounted at the heel of the shoe body, and is electrically connected to the battery; and
the battery is mounted at the counter of the shoe body, and is configured to connect the output interface for connecting a charging wire.

2. The shoe according to claim 1, wherein the heel of the shoe body is provided with a bottom groove, and the electricity generating apparatus is embedded in the bottom groove with an upper end in contact with a lower surface of an insole of the shoe body; and
the counter of the shoe body is provided with a side groove and a connection via hole, the battery is embedded in the side groove, and the connection via hole is aligned directly toward the output interface.

3. The shoe according to claim 2, wherein openings of the bottom groove and the side groove both face toward the inside the shoe body, the connection via hole faces toward the outside of the shoe body, and the connection via hole is covered with a cap.

4. The shoe according to claim 1, wherein the heel of the shoe body is provided with a bottom groove with an opening facing toward the inside of the shoe body, and the electricity generating apparatus is embedded in the bottom groove with an upper end in contact with a lower surface of an insole of the shoe body; and
the battery is mounted at an outer surface of a counter by using an adhesion fastener or a fixing clip, and the output interface faces toward the top of the shoe body or the rear of the shoe body.

5. The shoe according to claim 1, wherein both the electricity generating apparatus and the battery are wrapped by a thin water-proof film; and/or
the insole of the shoe body comprises an insulation layer and an exposure layer, the insulation layer is provided between the electricity generating apparatus and the exposure layer, and the insulation layer and the exposure layer are of a same size.

6. The shoe according to claim 1, wherein the electricity generating apparatus comprises a piezoelectricity electricity generating apparatus, a rectifying circuit, a capacitor, and a voltage-regulating charging circuit that are connected one by one, the battery comprises an energy-storage and discharging circuit and a lithium battery, and the energy-storage and discharging circuit is separately connected to the voltage-regulating charging circuit and the lithium battery, and is configured to store electrical energy into the lithium battery and supply stored electrical energy to a mobile terminal.

7. The shoe according to claim 6, wherein the piezoelectricity electricity generating apparatus is selectable from a piezoelectricity ceramic electricity generating apparatus or a multi-tooth electricity generating film.

8. The shoe according to claim 1, further comprising a charging wire configured to connect the battery and a mobile terminal, and being capable of extending from a foot of a user to a root of a thigh.

9. The shoe according to claim 8, further comprising a first fixing strap, a second fixing strap, and a third fixing strap, the first fixing strap is configured to fixing the charging wire to an ankle of the user, the second fixing strap is configured to fix the charging wire above a knee of the user, and the third fixing strap is configured to fix the charging wire to the thigh of the user.

10. The shoe according to claim 9, wherein at least one of the first fixing strap, the second fixing strap, and the third fixing strap is an adhesion strap or a buttoned strap.
